(19) United States
(12) Patent Application Publication
(10) Pub. No.: US 2012/0027968 A1
(43) Pub. Date: Feb. 2, 2012

(54) DEVICE HOUSING AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); CONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/150,354

(22) Filed: Jun. 1, 2011

(30) Foreign Application Priority Data
Jul. 29, 2010 (CN) 201010240082.9

(51) Int. Cl. B32B 1/02; C23C 14/34

(52) U.S. Cl. 428/34.1; 204/192.1

(57) ABSTRACT

A device housing is provided. The device housing includes a substrate, and an anti-fingerprint film formed on the substrate. The anti-fingerprint film is a metal-nitrogen-oxygen compound coating. A method for making the device housing is also described there.

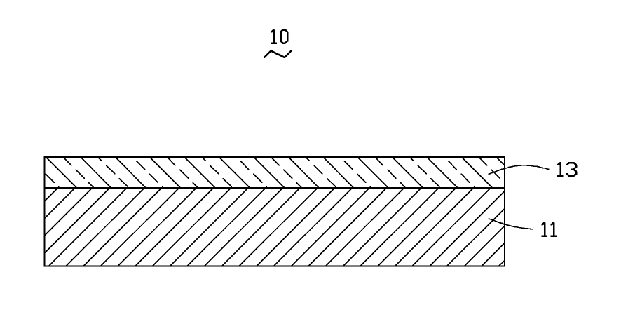

### CROSS-REFERENCE TO RELATED APPLICATIONS

This application is one of the three related co-pending U.S. patent applications listed below. All listed applications have the same assignee. The disclosure of each of the listed applications is incorporated by reference into all the other listed applications.

| Attorney | | |
|---|---|---|
| Docket No. | Title | Inventors |
| US 34428 | DEVICE HOUSING AND METHOD | HSIN-PEI CHANG |
| | FOR MAKING THE SAME | et al. |
| US 34432 | COATED ARTICLE AND METHOD | HSIN-PEI CHANG |
| | FOR MAKING THE SAME | et al. |
| US 34433 | COATED ARTICLE AND METHOD | HSIN-PEI CHANG |
| | FOR MAKING THE SAME | et al. |

### BACKGROUND

1. Technical Field

The present disclosure relates to device housings, particularly to a device housing having an anti-fingerprint property and a method for making the device housing.

2. Description of Related Art

Many electronic device housings are coated with anti-fingerprint film. These anti-fingerprint films are commonly painted with a paint containing organic anti-fingerprint substances. However, the print films are thick (commonly 2 μm-4 μm) and not very effective. Furthermore, the paint may not be environmentally friendly.

Therefore, there is room for improvement within the art.

### BRIEF DESCRIPTION OF THE FIGURE

Many aspects of the device housing can be better understood with reference to the following figure. The components in the figure are not necessarily drawn to scale, the emphasis instead being placed upon clearly illustrating the principles of the device housing.

The figure is a cross-section view of an exemplary embodiment of a device housing.

### DETAILED DESCRIPTION

The figure shows a device housing 10 according to an exemplary embodiment. The device housing 10 includes a substrate 11, and an anti-fingerprint film 13 formed on a surface of the substrate 11.

The substrate 11 may be made of metal or non-metal material. The metal may be selected from a group consisting of stainless steel, aluminum, aluminum alloy, copper, copper alloy, and zinc. The non-metal material may be plastic, ceramic, glass, or polymer.

The anti-fingerprint film 13 is a metal-nitrogen-oxygen compound coating. The metal-nitrogen-oxygen compound may be MₓO_{y}—N or MₓO_{y}—N—MeₓO_{y}—N, wherein M, Me are two different metals and may be selected from a group consisting of titanium (Ti), aluminum (Al), silicon (Si), chromium (Cr), and zirconium (Zr), provided M is different from Me. If M or Me is one of Ti, Si, and Zr, then ‘x’ and ‘y’ may have a relationship of y≧2x; if M or Me is one of Al and Cr, then ‘x’ and ‘y’ may have a relationship of y≧1.5x. That is, M or Me of the anti-fingerprint film 13 is completely oxidized with oxygen atoms. The values of ‘x’ and ‘y’ are not restricted in this embodiment. The metal-nitrogen-oxygen compound is amorphous. The anti-fingerprint film 13 has a good anti-fingerprint property.

The anti-fingerprint film 13 is transparent and very glossy. The anti-fingerprint film 13 has a thickness of only about 100-500 nm. The anti-fingerprint film 13 may be formed by an environmentally friendly vacuum sputtering process, and the anti-fingerprint film 13 is tightly bonded to the substrate 11.

Moreover, the nitrogen contained in the anti-fingerprint film 13 may further enhance the compactness and corrosion resistant properties of the anti-fingerprint film 13.

It is to be understood that, a color coating may be set between the substrate 11 and the anti-fingerprint film 13 to make the device housing 10 more attractive.

A method for making the device housing 10 may include the following steps:

The substrate 11 is provided and to be pretreated. The pre-treating process may include the following steps:

The substrate 11 is cleaned in an ultrasonic cleaning device (not shown) which is filled with ethanol or acetone.

The substrate 11 is plasma cleaned. The substrate 11 may be positioned in a plating chamber of a vacuum sputtering equipment (not shown). The plating chamber is fixed with a target therein. The target may be made of one or two of the elements selected from a group consisting of Ti, Al, Si, and Zr. The plating chamber is then vacuum pumped to about 4.0×10⁻³ Pa. Argon (Ar, having a purity of about 99.999%) may be used as a working gas and injected into the chamber at a flow rate of about 300-500 standard-state cubic centimeter per minute (sccm). The substrate 11 may be biased with negative bias voltage at a range of −300V to about −500 V, then high-frequency voltage is produced in the plating chamber and the Ar is ionized to plasma. The plasma then strikes the surface of the substrate 11 to clean the surface of the substrate 11. Plasma cleaning the substrate 11 may take about 3-10 minutes. The plasma cleaning process enhances the bonding between the substrate 11 and the anti-fingerprint film 13. The targets are unaffected by the pre-cleaning process.

The anti-fingerprint film 13 is vacuum sputtered on the pretreated substrate 11. Vacuum sputtering of the anti-fingerprint film 13 is implemented in the plating chamber of the vacuum sputtering equipment. The inside of the plating chamber is heated to about 20-300° C. Oxygen (O₂) and nitrogen (N₂) may be used as reaction gases and injected into the chamber at a flow rate of about 300-800 sccm and 100-400 sccm respectively, and argon (Ar) may be used as a working gas and injected into the chamber at a flow rate of about 300-500 sccm. Power is now applied to the target fixed in the plating chamber, and the substrate 11 may be biased with negative bias voltage to deposit the anti-fingerprint film 13 on the substrate 11. The negative bias voltage may be about −100 V to about −300 V. Depositing of the anti-fingerprint film 13 may take about 20-60 minutes.

It is to be understood that a color coating may be sputtered on the substrate 11 before sputtering the anti-fingerprint film 13. The color coating makes the device housing 10 more attractive.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A device housing, comprising:
a substrate; and
an anti-fingerprint film formed on the substrate, the anti-fingerprint film comprising a metal-nitrogen-oxygen compound coating.

2. The device housing as claimed in claim 1, wherein the coating of the metal-nitrogen-oxygen compound is MₓO_{y}—N or MₓO_{y}—N—MeₓO_{y}—N, in which M or Me is selected from a group consisting of titanium, aluminum, silicon, chromium, and zirconium, and if the coating of the metal-nitrogen-oxygen compound is MₓO_{y}—N—MeₓO_{y}—N, then M is different from Me.

3. The device housing as claimed in claim 2, wherein if the M or Me is one of titanium, silicon, and zirconium, ‘x’ and ‘y’ have a relationship of y≧2x.

4. The device housing as claimed in claim 2, wherein if the M or Me is one of aluminum and chromium, ‘x’ and ‘y’ have a relationship of y≧1.5x.

5. The device housing as claimed in claim 1, wherein the metal-nitrogen-oxygen compound is amorphous.

6. The device housing as claimed in claim 1, wherein the anti-fingerprint film has a thickness of about 100-500 nm.

7. The device housing as claimed in claim 1, wherein the substrate is made of metal or non-metal material.

8. The device housing as claimed in claim 7, wherein the metal is selected from a group consisting of stainless steel, aluminum, aluminum alloy, copper, copper alloy, and zinc, the non-metal material is selected from a group consisting of plastic, ceramic, glass, or polymer.

9. A method for making a device housing, comprising:
providing a substrate; and
forming an anti-fingerprint film on the substrate by vacuum sputtering, the anti-fingerprint film comprising a metal-nitrogen-oxygen compound coating.

10. The method as claimed in claim 9, wherein the metal-nitrogen-oxygen compound is MₓO_{y}—N or MₓO_{y}—N—MeₓO_{y}—N, in which M or Me is selected from a group consisting of titanium, aluminum, silicon, chromium, and zirconium, and if the metal-nitrogen-oxygen compound is MₓO_{y}—N—MeₓO_{y}—N, M is different from Me.

11. The method as claimed in claim 10, wherein if the M or Me is one of titanium, silicon, and zirconium, ‘x’ and ‘y’ have a relationship of y≧2x.

12. The method as claimed in claim 10, wherein if the M or Me is one of aluminum and chromium, ‘x’ and ‘y’ have a relationship of y≧1.5x.

13. The method as claimed in claim 9, wherein vacuum sputtering the anti-fingerprint film uses a target made of one or two of the elements selected from a group consisting of titanium, aluminum, silicon, chromium, and zirconium; uses oxygen and nitrogen as reaction gases, the oxygen has a flow rate of about 300-800 sccm, the nitrogen has a flow rate of about 100-400 sccm, uses argon as a working gas, the argon has a flow rate of about 300-500 sccm; vacuum sputtering the anti-fingerprint film is at a temperature of about 20-300° C., vacuum sputtering the anti-fingerprint film takes for about 20-60 minutes.

14. The method as claimed in claim 13, wherein the substrate is biased with a negative bias voltage of about −100V to about −300V during vacuum sputtering the anti-fingerprint film.

15. The method as claimed in claim 9, further comprising a step of pre-treating the substrate before forming the anti-fingerprint film.

16. The method as claimed in claim 15, wherein the pre-treating process comprising ultrasonic cleaning the substrate and plasma cleaning the substrate.

17. The method as claimed in claim 9, wherein the substrate is made of metal material or non-metal material.

18. The method as claimed in claim 17, wherein the metal is selected from a group consisting of stainless steel, aluminum, aluminum alloy, copper, copper alloy, and zinc, the non-metal material is selected from the group consisting of plastic, ceramic, glass, or polymer.
